(19) United States
(12) Patent Application Publication
(10) Pub. No.: US 2024/0346660 A1
(43) Pub. Date: Oct. 17, 2024

(54) SHAPE DETECTION TRANSFORMATION USING MEMRISTIVE IN-MEMORY COMPUTING

(71) Applicant: International Business Machines Corporation, Armonk, NY (US)

(72) Inventor: Ghazi Sarwat Syed, Kilchberg (CH)

(21) Appl. No.: 18/298,526

(22) Filed: Apr. 11, 2023

(51) Int. Cl. G06T 7/13; G06F 17/16; G11C 13/00

(52) U.S. Cl. CPC G06T 7/13; G06F 17/16; G11C 13/0069; G06T 2207/20061

(57) ABSTRACT

A method for a computational memory implementing a shape detection transformation using an integrated memristive computing crossbar array is disclosed. The method comprises using a first crossbar array tile of at least three crossbar tiles of a memristive computing crossbar array for a parametric space transformation of the shape detection transformation, wherein data of an image in a vectorized form is used as input for the first crossbar array, using an output of the first crossbar array tile as input for a second crossbar array tile for an accumulation operation of the shape detection transformation, and using an output of the second crossbar array tile as input for a third crossbar array tile for a shape tracing operation of the transformation, such that an output of the third crossbar array determines parameter values of a detected shape.

### BACKGROUND

The invention relates generally to a method for a shape detection transformation for shape detection, and more specifically, to a computer-implemented method for a computational memory implementing a shape detection transformation for shape detection using an integrated memristive computing crossbar array. The invention relates further to a shape detection transformation system for implementing a shape detection transformation for shape detection using an integrated memristive computing crossbar array, and a computer program product.

### SUMMARY OF THE INVENTION

According to one aspect of the present invention, a computer-implemented method for a computational memory implementing a shape detection transformation using an integrated memristive computing crossbar array may be provided. The method may comprise providing a memristive computing crossbar array having at least three crossbar tiles, using a first crossbar array tile of the at least three crossbar tiles for a parametric space transformation of the shape detection transformation, wherein data of an image in a vectorized form is used as input for the first crossbar array, using an output of the first crossbar array tile as input for a second crossbar array tile of the at least three crossbar tiles for an accumulation operation of the shape detection transformation, and using an output of the second crossbar array tile as input for a third crossbar array tile of the at least three crossbar tiles for a shape tracing operation of the transformation, such that an output of the third crossbar array determines parameter values of a detected shape.

According to another aspect of the present invention, a related shape detection transformation system for implementing a shape detection transformation for shape detection using an integrated memristive computing crossbar array may be provided. The system may comprise a memristive computing crossbar array having at least three crossbar tiles, a first crossbar array tile of the at least three crossbar tiles is adapted a parametric space transformation of the shape detection transformation, wherein data of an image in a vectorized form are connected to input lines of the first crossbar array, wherein an output of the first crossbar array tile is connected to an input circuit of a second crossbar array tile of the at least three crossbar tiles, wherein the second crossbar array tile is adapted for an accumulation operation of the shape detection transformation, and wherein an output of the second crossbar array tile is connected to an input circuit of a third crossbar array tile of the at least three crossbar tiles, wherein the third crossbar array tile is adapted for a shape tracing operation of the transformation, such that parameter values of a detected shape are available at an output of the third crossbar array.

The proposed computer-implemented method for a computational memory implementing a shape detection transformation for shape detection using an integrated memristive computing crossbar array may offer multiple advantages, technical effects, contributions and/or improvements:

The proposed concept can support machine-learning techniques in the critical step of shape detection and/or extraction of elements in images. It may directly support the technique called Hough transformation. This is used widely in image analysis, AI, computer vision, and digital image processing. It may advantageously solve the problem of lane detection and self-driving vehicles. This may be done in a resource efficient and elegant way. The reduction in computational latencies may be achieved by reducing the amount of data conversions and data in flow. It also may provide a reduction in computational energy costs by reducing their conversion rates and data movements.

Furthermore, the proposed concept may be compatible with existing in-memory technologies as well as related manufacturing methods.

And it may serve as a foundation for a plurality of use cases in many commercial applications, including autonomous robots, autonomous driving, and fault detection for quality assurance in industrial supply chains.

In the following, additional embodiments of the inventive concept-applicable for the method as well as for the system-will be described.

According to an advantageous embodiment, the method may comprise determining for each pixel with Cartesian coordinates x and y of the image before a vectorization a first conductance value G1=sin θ₁ for each x coordinate and G1=cos θ₁, and programming memristive device conductance values of two—in particular adjacent—word lines of the first crossbar array tile to values corresponding to G1 and G2 respectively. Thereby, θ and r may be polar coordinates corresponding pairwise to the Cartesian coordinates x and y, respectively, such that an accumulated current in the bit lines of the first crossbar array encode rᵢ values for each pairwise corresponding θᵢ. Hence, the proposed concept may allow a pretty elegant way of converting Cartesian coordinates into respective polar coordinates in a single step of the computational memory.

According to another advantageous embodiment, the method may further comprise assigning each resulting (rᵢ, θᵢ) pair of a memristive device of the second crossbar array tile, and analyzing the memristive device of the second crossbar array tile by: upon identifying—in particular a suitable—i.e., complying to user defined boundary conditions-combinations of (rᵢ, θᵢ), applying constant width or constant amplitude programming pulses to the respective memristive devices. Here, the advantage of the cells of the memristive crossbar array comes into play in that it can be used also for an analysis of certain conditions of incoming data. This may simply be done by applying programming pulses to various memristive devices in the crossbar array and looking for a bit line showing a highest output value; in particular, a simple comparison between values may deliver the desired result. This may be possible, because the accumulative increase in the device's conductance is achieved by consequent programming process.

According to an additional advantageous embodiment, the method may also comprise selecting the memristive device of the second crossbar array tile having received the highest number of programming pulses, and therefore having the highest conductivity G. Thereby, the suitable combinations of (rᵢ, θᵢ) relating to the selected memristive device may correspond to the polar coordinates (rₛ, θₛ) of a line in the image before a vectorization [“s” standing for “selected”]. Hence, applying the fundamental function of memristive crossbar arrays may lead directly to a line describable and polar coordinates.

According to a further embodiment, the method may also comprise determining a set of Cartesian coordinates (x_{L}, y_{L}) of the line by
(i) diagonally programming the memristive devices of the third crossbar array tile with conductance values G_{i,i} corresponding to determining conductance values

G_{L}=−cos θₛ/sin θₛ, and
(ii) applying amplitude signal value pulses—in particular, those corresponding to greyscale values of the image—of pixels of the vectorized image to pixels, having Cartesian coordinates xᵢ, i=1 . . . n, to the word lines of the third crossbar array tile, and
(iii) using resulting signals pulses yᵢ, i=1 . . . n on bit lines of the third crossbar array tile, such that value pair (xᵢ, yᵢ) represents an edge in the image. Therefore, it may also be a straightforward process to convert the polar coordinates back into Cartesian coordinates for visualizing the detected shape.

According to a permissive embodiment of the method, the memristive devices comprise PCM (phase change memory) devices, resistive memories, ferroelectric memories, magnetic tunnel junctions, electro-chemical memories, floating based memories, or charge based memories. Hence, the proposed inventive concept may literally implement any type of computational memory concept.

According to a useful embodiment of the method, each of the crossbar arrays may comprise at least one analog-to-digital converter (ADC) for each bit line of the crossbar arrays, a combined digital processing unit for all bit lines of the crossbar array, I/O logic and command control circuitry, a data buffer, an address-decoding circuitry, and a read/write circuitries. These additional components may be a useful additional electronic components for a proper operation of the memristive crossbar array to be operational as computational memory.

According to an interesting embodiment of the method, the transformation is a Hough transformation. Such a transformation is known to be useful for any kind of application in which it is required to detect edges or borderlines of object in images—also images of videos, respectively—for a 3-dimensional orientation of a robotic system, like autonomous driving car, pick-and-place robots, and any other system in which the system needs to find its orientation in a 3-dimensional room.

According to an advanced embodiment of the method, the at least three crossbar tiles of the memristive computing crossbar array may be different sub-crossbar arrays of a larger memristive computing crossbar array using common interfacing circuits. Hence, it may also be possible to use the same crossbar for all stages of the method by using different areas of the crossbar for different operations. Thus, there may be different implementation options depending on the type of memristive crossbar array used.

According to a practical embodiment, the method may also comprise highlighting pixels of the detected shape in the (original) image which may have been used as starting point for the method. Additionally, it may be of practical use to displaying the detected line within the original image. This may be implemented, e.g., as a visibly highlighted overlay line for a good visibility to a user. One example may be a red line in an image for a lane of a street on a screen in a car in order to show the driver the border line of the street, or in a broader sense: lane or path detection.

Furthermore, embodiments may take the form of a related computer program product, accessible from a computer-usable or computer-readable medium providing program code for use by or in connection with a computer or any instruction execution system by or in connection with a computer or any instruction execution system. For the purpose of this description, a computer-usable or computer-readable medium may be any apparatus that may contain means for storing, communicating, propagating or transporting the program for use by or in connection, with the instruction execution system, apparatus, or device.

### BRIEF DESCRIPTION OF THE DRAWINGS

It should be noted that embodiments of the invention are described with reference to different subject-matters. In particular, some embodiments are described with reference to method type claims, whereas other embodiments are described with reference to apparatus type claims. However, a person skilled in the art will gather from the above and the following description that, unless otherwise notified, in addition to any combination of features belonging to one type of subject—matter, also any combination between features relating to different subject—matters, in particular, between features of the method type claims, and features of the apparatus type claims, is considered as to be disclosed within this document.

The aspects defined above and further aspects of the present invention are apparent from the examples of embodiments to be described hereinafter and are explained with reference to the examples of embodiments to which the invention is not limited.

Preferred embodiments of the invention will be described, by way of example only, and with reference to the following drawings:

FIG. 1 shows a block diagram of an embodiment of the inventive computer-implemented method for a computational memory implementing a shape detection transformation for shape detection using an integrated memristive computing crossbar array.

FIG. 2 shows a block diagram of the principle of a Hough transformation.

FIG. 3 shows a block diagram of a tiled memristive crossbar array as used in an embodiment of the inventive concept.

FIG. 4 shows a block diagram of an embodiment of steps of the proposed method executed by different tiles of the memristive crossbar array.

FIG. 5 shows a block diagram of an embodiment of additional components instrumental for a working computational memory.

FIG. 6 shows a block diagram of the memristor crossbar tiles being programmed with pules.

FIG. 7 shows more details of the memristive crossbar and array tiles shown in the overview FIG. 6.

FIG. 8 shows a small portion of a crossbar array of FIG. 6 which allows to reconstruct the line using in-memory approach.

FIG. 9 shows a block diagram of an embodiment of the inventive shape detection transformation system for implementing a shape detection transformation for shape detection using an integrated memristive computing crossbar array.

FIG. 10 shows an embodiment of a computing system comprising the system according to FIG. 9.

FIG. 11 shows an example of detecting lines bringing all elements together.

### DETAILED DESCRIPTION

In the context of this description, the following technical conventions, terms and/or expressions may be used:

The term ‘computational memory’ may denote a core element of a novel type of processing core, different to traditional von Neumann CPUs. The computational memory may have typically a plurality of conductive word lines and another plurality of conductive bit lines. At each cross point of the word lines and the bit lines a memristive memory cell may be positioned. Typically, the conduct to have status of the respective memristive memory cells may be programmed according to requirements. Input, output and program circuitries complete the computational memory architecture.

The term “shape detection transformation” may denote here that all required determinations and computations may be performed within a single computing architecture, namely a computational memory without the need for performing parts of it in traditional von Neumann CPUs. In this sense, the shape detection transformation may also be denotes as an end-to-end transformation for shape detection being executed using memristive devices. However, a traditional von Neumann controller may be used to control the operation of the computational memory. In any case, a complete Hough transformation may be performed within one architecture and literally within one computing step. In the other side, one may also choose to perform some steps of the shape detection using traditional computing architectures (e.g. von Neumann), e.g., for accuracy reasons.

The term “shape detection” may denote a mechanism for a recognition of edges—i.e., border lines—in digital images between different elements of the image.

The term “integrated memristive computing crossbar array” may denote a computing device comprising at least the computational memory, as described above. The device may also comprise a plurality of memristive computing crossbar arrays as well as controlling electronic.

The term “crossbar array tiles” may denote a sub-section of a larger computational memory device, where a potentially larger crossbar may have been cut into sub-crossbar, denoted as tiles.

The term “parametric space transformation” may denote an MVM, i.e., a matrix vector multiplication.

The term “data of an image in a vectorized form” may denote pixels or intensity values (either grayscale or intensities of values of RGB pixels), where each pixel of the image may represent one dimension of the vector. Consequently, a matrix representing an image of size m*n would be transformed into a matrix of size (m*n, 1), i.e., a vector.

The term “accumulation operation” or voting procedure may denote adding programming pulses within the computational memory, in particular, in specific memristive crossbar cells connected between respective word lines and bit lines. The one or memristive crossbar cell receiving the majority of programming pulses may have the lowest conductivity of all memristive crossbar cells in the crossbar array. This very memristive crossbar cell may then represent the respective searched parameter values, e.g., rₛ and θₛ (“s” representing “selected”).

The term “shape tracing operation” may denote an operation performed in the crossbar array for determining the constant values m and C of a line equation y=m*x+c.

The term “word lines” may denote—depending on the reference coordinate system—horizontal lines of the crossbar array connected to input terminals or an input circuitry.

The term “bit line” may denote—depending on the reference coordinate system—a vertical line of the crossbar array connected to output terminals or an output circuitry (e.g., ADC and processing circuitry).

The term “Hough transformation” may denote the known feature extraction techniques used in image analysis, computer vision and digital image processing. The purpose of these techniques is to find in perfect instances of objects within a certain class of shapes by a voting procedure.

Highly advanced semiconductor technologies seem to come closer and closer to an end of Moore's Law using current computing architectures, in particular, the ever present von-Neumann computer system architecture. Therefore, research and industry look for alternative computing architectures overcoming the limits of traditional von-Neumann architectures comprising traditional digital main memory and a central processing unit with registers for storing operands and instructions.

One promising approach—among others—is the usage of neuromorphic computing memristors organized in crossbar arrays with input, output and control electronics. Computing devices based on this new technology have been used successfully to simulate behaviors of synapses and neurons, making these devices promising candidates for brain-inspired computing. Organized in large-scale crossbar arrays, the memristors crossbar arrays can perform efficient in-memory computing with massive and high efficient parallelism. These devices are also able to interact with analogue devices—in particular, using them as input signal generator (e.g., image sensors)—without requiring analog/digital converters. This may also reduce processing time and energy consumption.

Typically, memistors, which can be programmed to have one of several conductance values, are used at each crossing point of word lines and bit lines of the crossbar arrays.

One application area, in which the memristive computational devices have proven to be successful is image analysis. A more specific area may be seen in shape recognition. However, known technologies in this field have their shortcoming.

Some documents describe parts of memristive computing. For example, document U.S. Pat. No. 11,294,985 B2 describes techniques for efficient matrix multiplication using in-memory analog parallel processing, with applications for neural networks and artificial intelligence processors. For this, two matrices are stored in memory. The first matrix is stored in transposed form such that the transposed first matrix has the same number of rows as the second matrix. In general, the related device capable performing dot products that correspond to elements of the matrix multiplication product of the two matrices.

While matrix multiplications are one example of a successful application of memristive computing devices, engineers are constantly looking to extend the application areas of memristive computing devices.

In the following, a detailed description of the figures will be given. All instructions in the figures are schematic. Firstly, a block diagram of an embodiment of the inventive computer-implemented method for a computational memory implementing a shape detection transformation for shape detection using an integrated memristive computing crossbar array is given. Afterwards, further embodiments, as well as embodiments of the shape detection transformation system for implementing a shape detection transformation for shape detection using an integrated memristive computing crossbar array will be described.

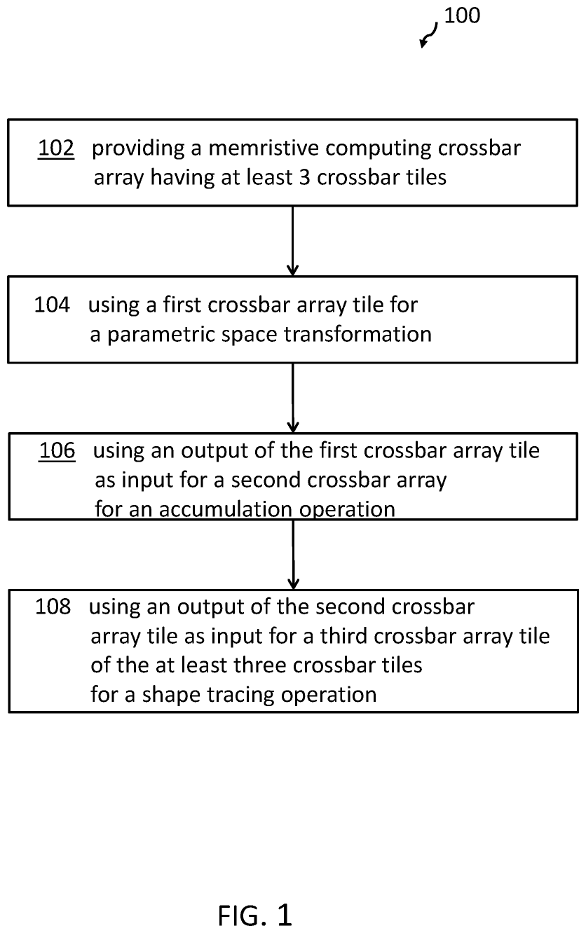

FIG. 1 shows a block diagram of a preferred embodiment of the computer-implemented method 100 for a computational memory implementing a shape detection transformation—e.g., Hough transformation—for shape detection using an integrated memristive computing crossbar array. The method comprises providing. 102, a memristive computing crossbar array having at least three crossbar tiles and using. 104, a first crossbar array tile of the at least three crossbar tiles for a parametric space transformation of the shape detection transformation. Thereby, data of an image in a vectorized form is used as input for the first crossbar array. This may also include a color to gray scale conversion so that the subsequent grayscale is used as intensity signal in the form of vector component signals with constant amplitude and varying width. I.e., the greyscale intensity is converted to a PWM (pulse wide modulation) signal vector.

The method 100 comprises further using, 106, an output of the first crossbar array tile as input for a second crossbar array tile of the at least three crossbar tiles for an accumulation operation of the shape detection transformation, and using, 108, an output of the second crossbar array tile as input for a third crossbar array tile of the at least three crossbar tiles for a shape tracing operation of the transformation, such that an output of the third crossbar array determines—in particular, at least one—parameter value—in particular, (−cos θ/sin θ) of a detected shape, e.g., a line, an edge or a body, etc. Because in this embodiment all determinations and transformations required for the shape detection are performed by a consistent in-memory computing architecture, i.e., the memristive crossbar array based computational memory, the transformation for a shape detection can also be denote as an end-to-the transformation using memristive crossbar arrays.

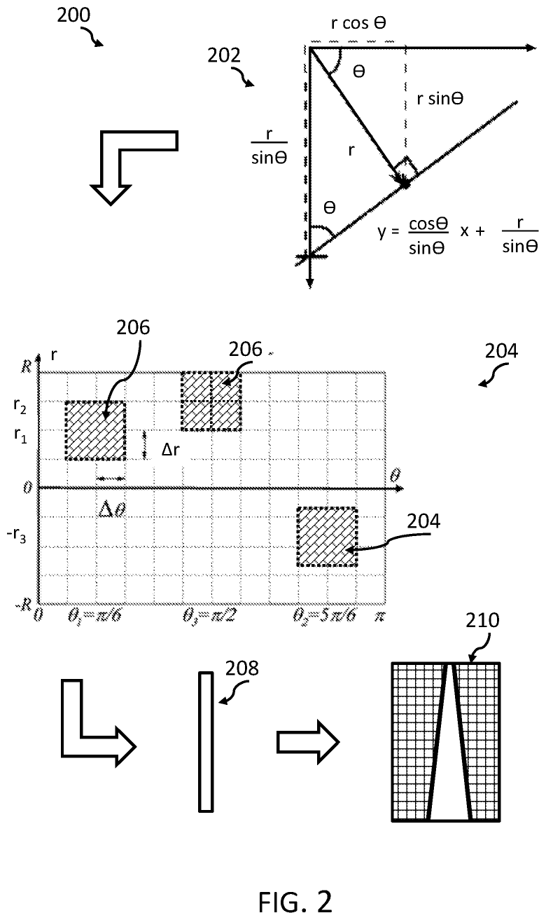

FIG. 2 shows a block diagram 200 of the principle of a Hough transformation. In one framework, the Hough transformation converts the Cartesian plain 202—using coordinates x, y—into a polar coordinate space, in which every point—e.g., an edge in an image—gets represented by the parameters r and θ. In the polar coordinate space, the goal is finding the common trace (e.g., a line or a fraction thereof) between the data points. This procedure involves a linear operation in determining r and θ for data points following by a voting mechanism. Using traditional technologies and computing architectures, this makes the Hough transformation a computationally expensive process.

In a first step, mainly related to the Cartesian space 202, for every relevant pixel, in particular that of an average in an image, the first goal is determining all r for all possible θ. Hence, for N relevant pixels the operations shown in the sub-FIG. 202 is performed N*M times, where M is a vector of length k encoding all possible θ. The structured squares in sub-FIGS. 204 and 206 are examples representing the searched edges or borderline.

In a second step, the goal is finding a common r and θ among many pixels. For that, in a cumulative matrix of size M*P (P>M) is used to determine the combination of r and θ. Each time a certain combination is found, the corresponding matrix element is incremented. Thus, the element with large or the largest value encode the common line between the points. This may be represented by the vector 208, for which the large values in the matrix are filtered and the corresponding r and θ are stored. Finally, using the plurality of r and θ, the lines are constructed and overlaid to the original image 210, where the area 212 may represent, e.g., a detected street lane.

Because the computations relating to sub-FIG. 202, sub-FIG. 204 and the lower part of FIG. 2 comprising vector 208 and the overlay image 210 are recursive, many data accesses are involved when using a traditional von Neumann machine. In particular, when N gets large, the computation becomes expensive in both, in energy and latency. The concept proposed here, addresses this dilemma.

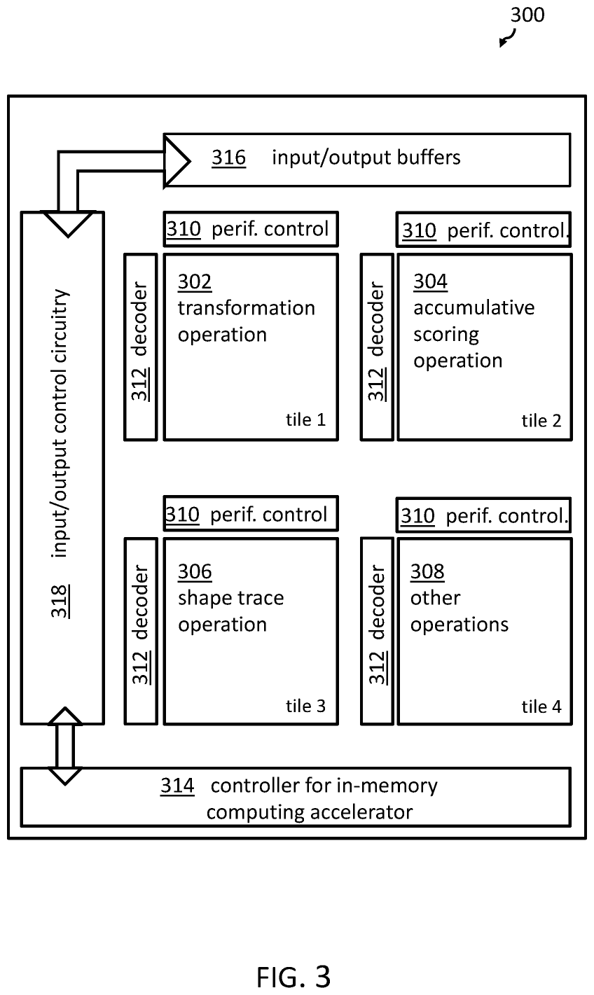

FIG. 3 shows a block diagram of a tiled memristive crossbar array 300 as used in an embodiment of the inventive concept. In the core of the figure, four different memristive crossbar arrays are shown, denoted as tile 1, tile 2, tile 3 and tile 4. It forms the core of the computational memory which interfaces with the host via a host interface connected to the input/output control circuit 318 to perform transformation operations 302, e.g., in-memory MVM (matrix vector multiplication) and accumulative scoring operations 304 as well as shape tracing operation 306. Tile 4 can optionally be used for other operations 308.

Each of the tiles 1 to 4 can comprise its own peripheral control circuitry 310, as well as its own address decoder 312. In other embodiments, the peripheral control circuitry 314, e.g., analog-to-digital and other digital signal processing, and the address decoder 312 may be used—in a slightly modified form—for all three or four sub- or tile-crossbar arrays. Furthermore, various input/output buffers 316, read/write circuitry and others may be instrumental for the tiled memristive crossbar array 300.

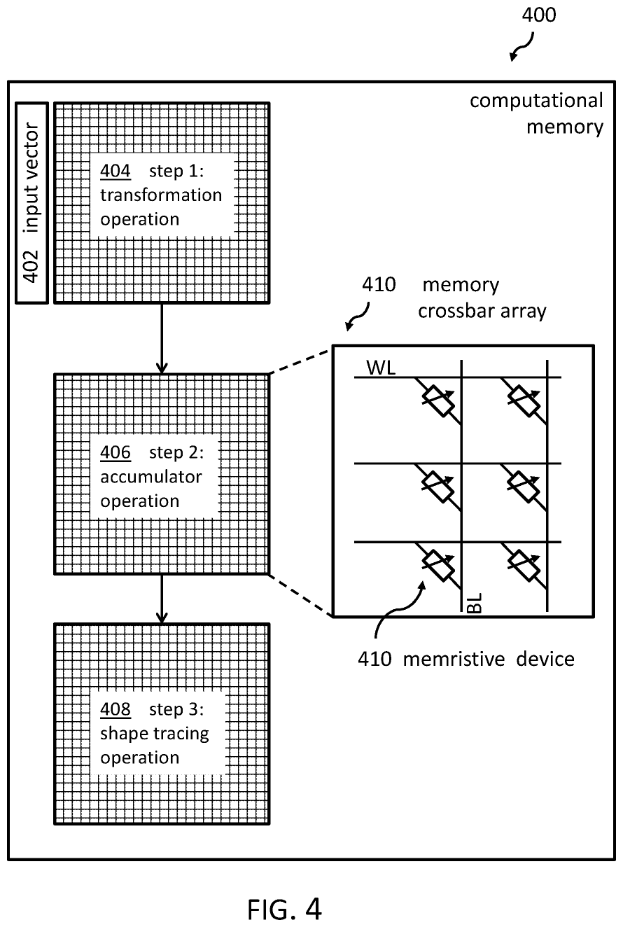

FIG. 4 shows a block diagram of an embodiment of steps of the proposed method executed by different tiles of the memristive crossbar array—in particular, the computational memory 400—from a different perspective. After receiving the input vector 402—in particular, in the form of a vectorized image—firstly, a transformation operation 404 is performed as step one by the first tile of the tired crossbar array. In the second tile of the tired crossbar array, the second step, namely the accumulator operation 406 can be executed. Finally, in the third step, the shape tracing operation 408 can be performed in the third tile of the tiled memristive crossbar array.

The partial enlargement 410 of the memristive crossbar array shows, as an example, for the plurality of word lines, 3 of them running horizontally, while the plurality of bit lines—two of them are shown as example—run vertical. Typically, the word lines are used as input lines, whereas the bit lines are used as lines running to output circuitries of the memristive crossbar array, e.g., ADCs. At each cross point of a word line and a bit line, a programmable resistive—i.e., memristive—device is shown.

Because all three sub-operations of the shape detection transformation—in particular the Hough transformation—can be performed within the in-memory computing scheme, significant gains in energy efficiency and reduction in computational latency can be achieved.

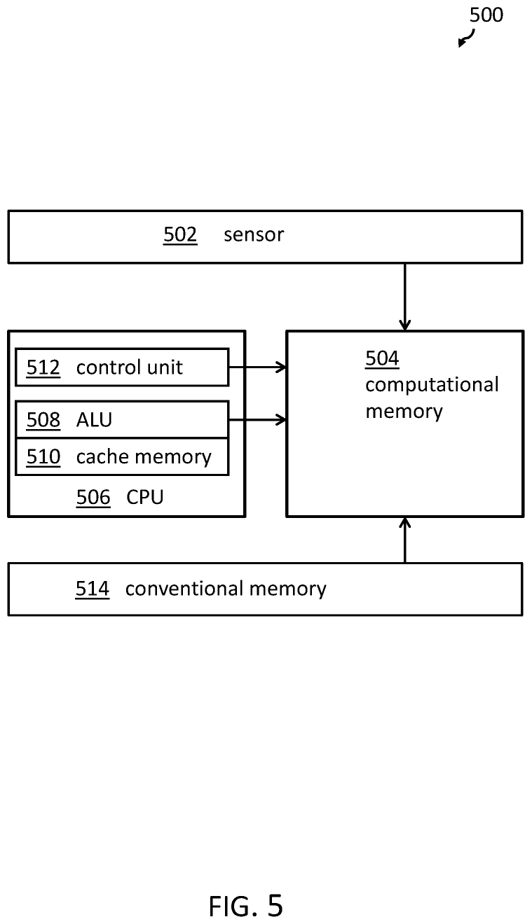

FIG. 5 shows a block diagram of an embodiment of additional components useful for a working computational memory device 500. As an example, this computational memory device 500 is shown with only one internal computational memory 504. The sense of 502—e.g., an image sensor—can more or less directly interface with the computational memory. Eventually, a buffer may be required. However, the analog values of the sensor 502 may be used as direct input to the computational memory 504. A traditional CPU or controller 506 comprising some control logic in control unit 512, and ALU 508 (arithmetic logical unit) and optionally cache memory 510 can be used to control the operation of the computational memory 504 with the help of conventionally computer memory 514. This way, the advantageous characteristics of the computational memory 504 can be fully exploited.

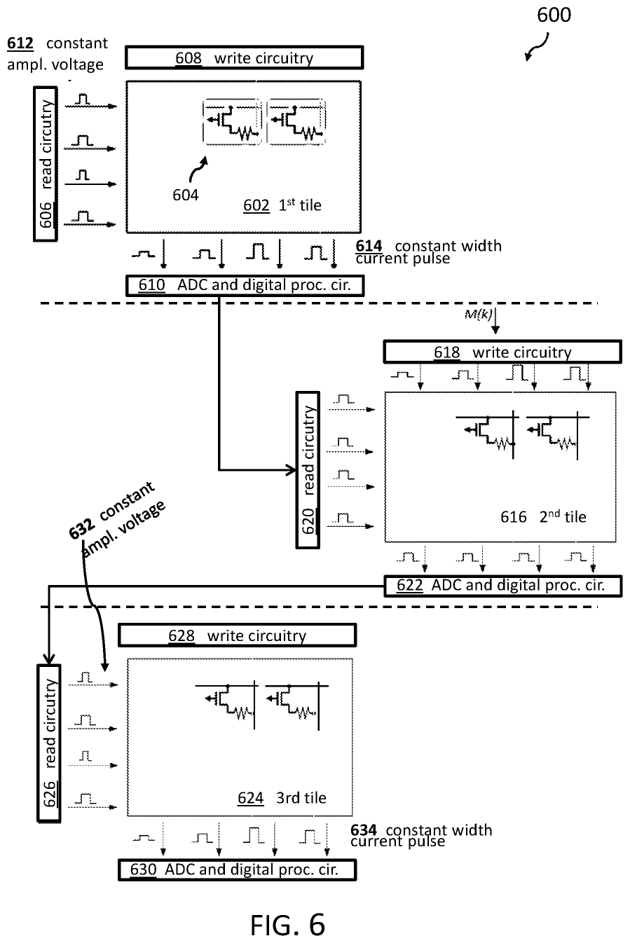

FIG. 6 shows a block diagram 600 of the memristive crossbar tiles being programmed with pules. The top portion of FIG. 6 refers to the first tile of a memristive crossbar array 602, symbolized by two memristive cells 604. This memristive crossbar array 602 is responsible for the in-memory transformation operation (i.e., basically, the vector matrix multiplication).

Also shown are the input or read circuitry 606, the write circuitry 608—which is used for programming their memristive cells 604—and the output or ADC (analog/digital converter), and digital processing circuitry. It should be noted, that the input signals (of which four are exemplary shown) are coded as constant amplitude voltage signals 612 with a variable width. In contrast, the output signals of the memristive crossbar array 602 are shown as constant width current pulses 614 (four of which are shown as examples) with a variable amplitude. It should also be understood that the number of input lines to the crossbar array 602 is typically equal to the number of word lines of the crossbar array 602. The same applies to the number of output signals and the number of bit lines in the crossbar array 602 (compare FIG. 4).

The middle part of FIG. 6 relates to the in-memory accumulative scoring operation performed by the second tile 616 of memristive crossbar arrays. Also here, a respective write circuitry 618, a read circuitry 620 and the ADC and digital processing circuitry 622 are shown. The output of the ADC and digital processing circuit 610 is used as direct input to the read circuitry 620. Input for the write circuitry would be the collective momentum estimated from the outputs of the transformation operation, namely M(k).

The output at the ADC and digital processing circuitry 622 of the second tile 616 is used as direct input to the read circuitry 626 of the third tile 624 of crossbar arrays, which again comprises a write circuitry 628 as well as an ADC and digital processing circuitry 630. It should be noted that, here again, the input to the crossbar array of the third tile 624 is encoded as constant amplitude voltage 632, whereas the signals leaving the third tile 624 of crossbar arrays as constant width current pulses 634.

In the context of the following two figures, more details about the processes within and between the first, second and third tile of memristive crossbar arrays will be explained.

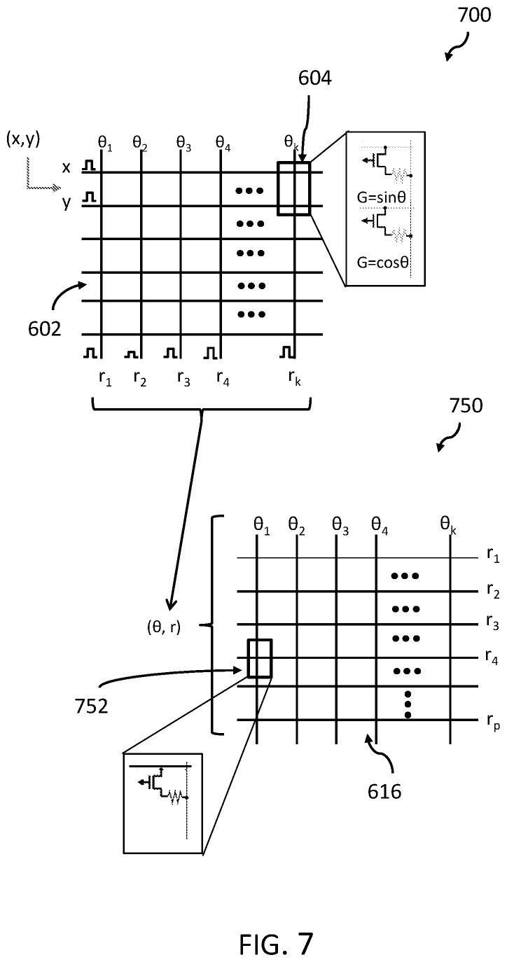

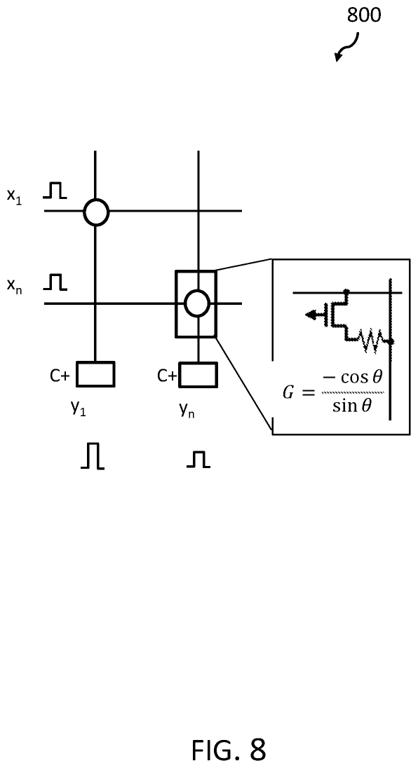

FIG. 7 shows a diagram 700, 750 of more details of the first two memristive crossbar array tiles shown in the overview of FIG. 6. Details of the third memristive crossbar array of FIG. 6 will be discussed in the context of FIG. 8.

Diagram 700 relates to the crossbar array 602 of FIG. 6. It shows again symbolically input values x,y which are fed to two (adjacent) word lines of the crossbar array 604 in order to generate the different rᵢ-values, i=1 . . . n. Thereby, rectangle 702 illustrates symbolically, how the memristive crossbar array cells of the index and why word lines and the θₖ/rₖ bit line are programmed, namely the upper memristive crossbar array cell with a conductive value G=sin θₖ and the lower memristive crossbar array cell with a conductive value of G=cos θₖ.

I.e., the crossbar array 602 takes coordinates of relevant pixels in an image and determines or computes the values of rᵢ. In essence, this provides all combinations of r and θ and it is achieved by encoding sin θ and cos θ in the conductance of the devices in the crossbar array 602. The accumulated current in the bit lines encode the respective values of rᵢ.

Diagram 750 relates to the crossbar array 616 of FIG. 6. In this block, the in-memory voting (or accumulation) happens. The rectangle 752 again shows an example of an memristive crossbar array cell between a word line and a respective bit line. In this crossbar array, every rᵢ, θₖ combination is assigned to a memory device. If a certain combination is noted when analyzing a certain pixel, a programming pulses is applied to the device. At the end of the process, all the devices are read. Devices with the largest output value accumulate the largest number of the programming pulses. They therefore correspond to the polar parameter values of a “line” (i.e., a line through the edges of the original image) and represent the co-linear pixels.

FIG. 8 shows a small portion 800 of the crossbar array 624 of FIG. 6 which allows to reconstruct the line using in-memory approach of the memristive crossbar array technology. With (r, θ) it then becomes possible to plot the line using the equation y=(−cos θ)/(sin θ)*x+r/(sin θ) which represents a classical line equation y=m*x+c. With x and x₁ as inputs, y₁ and yₙ has to be determined (or computed). This is achieved by using the crossbar with a diagonal encoding as shown in FIG. 8, where the variables of the line equations are used. The conductance of the relevant memristive crossbar array cells are programmed with the following value G=(−cos θ)/(sin θ) which represents m in the line equation.

This is performed with the third step of the shape detection transformation, namely the shape tracing operation (compare 408, FIG. 4). Furthermore, computations on all elements in (θ, r) can be performed quasi-parallel with the crossbar array 624. Hence, the in-memory approach allows for the shape detection determination of the Hough transformation.

It shall also be noted that the programming of the memristive crossbar cells according to the values of θₖ is programmed by the controller of the computational memory, e.g., a traditional von Neumann CPU (compare FIG. 5)

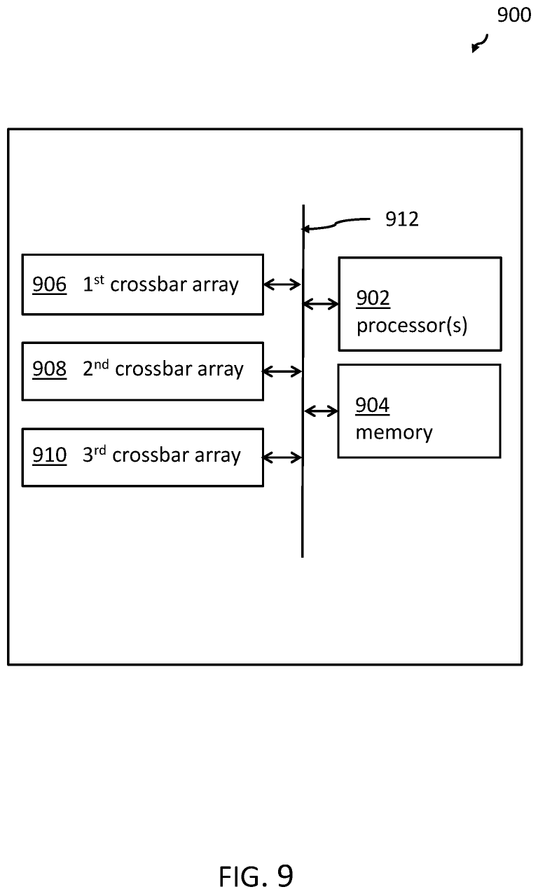

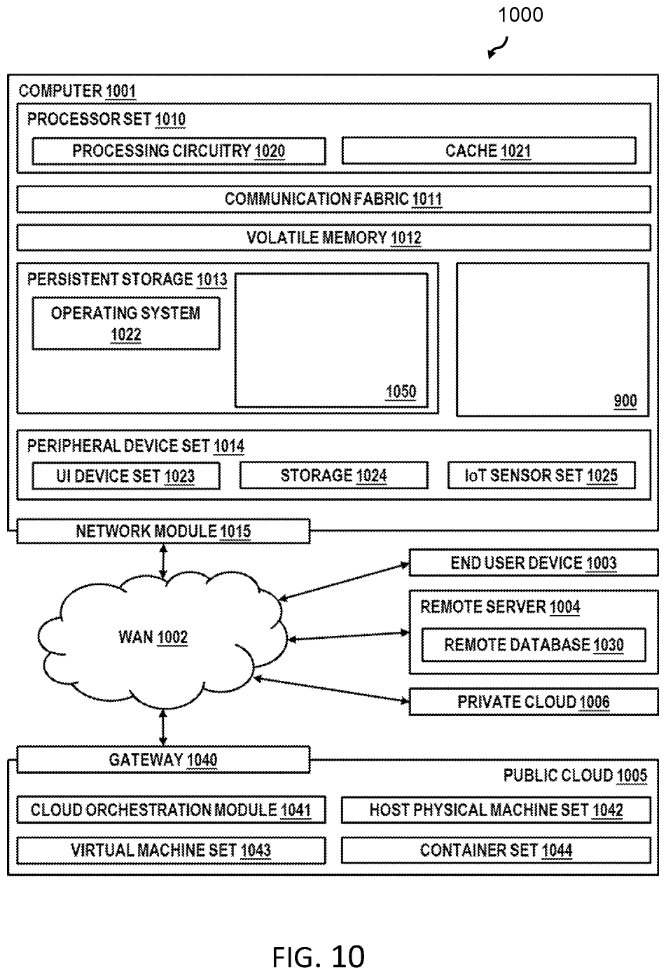

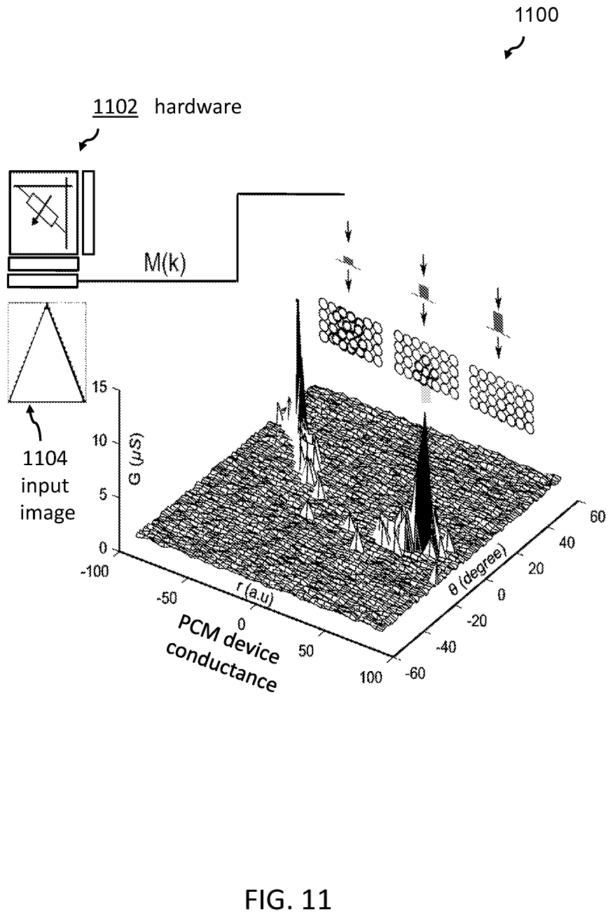

Before turning to FIGS. 9 and 10, a short impression or overview 1100, using FIG. 11, may be given, where an example of the detecting of lines that brings all elements together is shown. The used memristive crossbar array hardware 1102 generates the weighing factors of the accumulation of voting process, resulting in M(k), the collective momentum estimated from the outputs of the transformation operation. The input image comprises a plurality of dots, denoted as edges, where some of the edges represent a line. It may also be noted that the x and y coordinates may represent memristive crossbar array cells. The spikes in the conductance values are well-suited to represent or characterize the lines of the input image.

FIG. 9 shows a block diagram of an embodiment of the shape detection transformation system 900 for implementing a shape detection transformation for shape detection using an integrated memristive computing crossbar array. The system 900 comprises a memristive computing crossbar array, having at least three crossbar tiles 906, 908, 910. In particular, the system 900 comprises a first crossbar array tile 906 of the at least three crossbar tiles adapted to a parametric space transformation of the shape detection transformation, wherein data of an image in a vectorized form are connected to input lines of the first crossbar array. Thereby, an output of the first crossbar array tile 906 is connected to an input circuit of a second crossbar array tile 304, 406, 616 of the at least three crossbar tiles, wherein the second crossbar array tile is adapted for an accumulation operation of the shape detection transformation.

Furthermore, an output of the second crossbar tile array 908 is connected to an input circuit of a third crossbar array tile 910 of the at least three crossbar tiles, where the third crossbar array tile is adapted for a shape tracing operation of the transformation, such that at an output of the third crossbar array parameter values of a detected shape are available.

It shall also be mentioned that all functional units, modules and functional blocks—in particular, the processor(s) 902, the memory 904, the first crossbar array 906 (compare also 302, 404, 62), 908 (compare also 304, 406, 616), the third crossbar array 608 (compare also 306, 408, 624)—may be communicatively coupled to each other for signal or message exchange in a selected 1:1 manner. Alternatively the functional units, modules and functional blocks can be linked to a system internal bus system 912 for a selective signal or message exchange.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (CPP embodiment or CPP) is a term used in the present disclosure to describe any set of one, or more, storage media (also called mediums) collectively included in a set of one, or more, storage devices that collectively include machine readable code corresponding to instructions and/or data for performing computer operations specified in a given CPP claim. A storage device is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 10 shows a computing environment 1000 comprising an example of an environment for the execution of at least some of the computer code involved in performing the inventive methods, such as the computer-implemented method for a computational memory implementing the shape detection transformation for shape detection using an integrated memristive computing crossbar array 1050.

In addition to block 1050, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 1050, as identified above), peripheral device set 1014 (including user interface (UI), device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

COMPUTER 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 10. On the other hand, computer 1001 is not required to be in a cloud except to any extent as may be affirmatively indicated.

PROCESSOR SET 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 1050 in persistent storage 1013.

COMMUNICATION FABRIC 1011 is the signal conduction paths that allow the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1012 is any type of volatile memory now known or to be developed in the future. Examples include dynamic type random access memory (RAM) or static type RAM. Typically, the volatile memory is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

PERSISTENT STORAGE 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid state storage devices. Operating system 1022 may take several forms, such as various known proprietary operating systems or open source Portable Operating System Interface type operating systems that employ a kernel. The code included in block 1050 typically includes at least some of the computer code involved in performing the inventive methods.

PERIPHERAL DEVICE SET 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion type connections (e.g., secure digital (SD) card), connections made though local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

NETWORK MODULE 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (e.g., embodiments that utilize software-defined networking (SDN)), the control functions and the forwarding functions of network module 1015 are performed on physically separate devices, such that the control functions manage several different network hardware devices. Computer readable program instructions for performing the inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1003 is any computer system that is used and controlled by an end user (for example, a customer of an enterprise that operates computer 1001), and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

REMOTE SERVER 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

PUBLIC CLOUD 1005 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

It should also be mentioned that the shape detection transformation system for implementing the shape detection transformation for shape detection using an integrated memristive computing crossbar array 900 can be an operational sub-system of the computer 1001 and may be attached to a computer-internal bus system.

The terminology used herein is for the purpose of describing particular embodiments only and is not intended to limit the invention. As used herein, the singular forms a, an and the are intended to include the plural forms as well, unless the context clearly indicates otherwise. It will further be understood that the terms comprises and/or comprising, when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or steps plus function elements in the claims below are intended to include any structure, material, or act for performing the function in combination with other claimed elements, as specifically claimed. The description of the present invention has been presented for purposes of illustration and description, but is not intended to be exhaustive or limited to the invention in the form disclosed. Many modifications and variations will be apparent to those of ordinary skills in the art without departing from the scope and spirit of the invention. The embodiments are chosen and described in order to best explain the principles of the invention and the practical application, and to enable others of ordinary skills in the art to understand the invention for various embodiments with various modifications, as are suited to the particular use contemplated.

What is claimed is:

1. A method for a computational memory implementing a shape detection transformation using an integrated memristive computing crossbar array, the method comprising
providing a memristive computing crossbar array having at least three crossbar tiles,
using a first crossbar array tile of the at least three crossbar tiles for a parametric space transformation of the shape detection transformation, wherein data of an image in a vectorized form is used as input for the first crossbar array,
using an output of the first crossbar array tile as input for a second crossbar array tile of the at least three crossbar tiles for an accumulation operation of the shape detection transformation, and
using an output of the second crossbar array tile as input for a third crossbar array tile of the at least three crossbar tiles for a shape tracing operation of the transformation, such that an output of the third crossbar array determines parameter values of a detected shape.

2. The method according to claim 1, further comprising
determining for each pixel with Cartesian coordinates x and y of the image before a vectorization a first conductance value G1=sin θ₁ for each x coordinate and G1=cos θ₁, and
programming memristive device conductance values of two word lines of the first crossbar array tile to values corresponding to G1 and G2 respectively,
wherein θ and r are polar coordinates corresponding pairwise to the Cartesian coordinates x and y, respectively,
such that an accumulated current in the bit lines of the first crossbar array encode rᵢ values for each pairwise corresponding θᵢ.

3. The method according to claim 2, further comprising
assigning each resulting (rᵢ, θᵢ) pair a memristive device of the second crossbar array tile, and
analyzing the memristive device of the second crossbar array tile by
upon identifying combinations of (r, θ), applying constant width or constant amplitude programming pulses to the respective memristive devices

4. The method according to claim 3, further comprising
selecting the memristive device of the second crossbar array tile having received a highest number of programming pulses, wherein the suitable combinations of (r, θ) relating to the selected memristive device correspond to the polar coordinates (rₛ, θₛ) of a line in the image before the vectorization.

5. The method according to claim 4, further comprising
determining a set of Cartesian coordinates (x_{L}, y_{L}) of the line by
(i) diagonally programming the memristive devices of the third crossbar array tile with conductance values G_{i,i} corresponding to determining conductance values GL=−cos θₛ/sin θₛ, and
(ii) applying amplitude signal value pulses of pixels of the vectorized image, the pixels having Cartesian coordinates xᵢ, i=1 . . . n, to e word lines of the third crossbar array tile, and
(iii) using resulting signals pulses yi, i=1 . . . n on bit lines of the third crossbar array tile such that value pair (xᵢ, yᵢ) represent an edge in the image.

6. The method according to claim 2, wherein the memristive devices comprise PCM devices, resistive memories, ferroelectric memories, magnetic tunnel junctions, electro-chemical memories, floating based memories, and charge based memories.

7. The method according to claim 1, wherein each of the crossbar arrays comprise at least one of an analog-to-digital converter for each bit line of the crossbar arrays, a combined digital processing unit for all bit lines of the crossbar array, I/O logic and command control circuitry, a data buffer, address-decoding circuitry, a read/write circuitry.

8. The method according to claim 1, wherein the transformation is a Hough transformation.

9. The method according to claim 1, wherein the at least three crossbar tiles of the memristive computing crossbar array are different sub-crossbar arrays of a larger memristive computing crossbar array using coming interfacing circuits.

10. The method according to claim 1, further comprising
highlighting pixels of the detected shape in the image.

11. A shape detection transformation system for implementing a shape detection transformation using an integrated memristive computing crossbar array, the system comprising
a memristive computing crossbar array having at least three crossbar tiles,
a first crossbar array tile of the at least three crossbar tiles is adapted a parametric space transformation of the shape detection transformation, wherein data of an image in a vectorized form are connected to input lines of the first crossbar array,
wherein an output of the first crossbar array tile is connected to an input circuit of a second crossbar array tile of the at least three crossbar tiles, wherein the second crossbar array tile is adapted for an accumulation operation of the shape detection transformation, and
wherein an output of the second crossbar array tile is connected to an input circuit of a third crossbar array tile of the at least three crossbar tiles, wherein the third crossbar array tile is adapted for a shape tracing operation of the transformation, such that at an output of the third crossbar array parameter values of a detected shape are available.

12. The system according to claim 11, further comprising
determining for each pixel with Cartesian coordinates x and y of the image before a vectorization a first conductance value G1=sin θ₁ for each x coordinate and G1=cos θ₁, and
programming memristive device conductance values of two word lines of the first crossbar array tile to values corresponding to G1 and G2 respectively,
wherein Î^{˜} and r are polar coordinates corresponding pairwise to the Cartesian coordinates x and y, respectively,
such that an accumulated current in the bit lines of the first crossbar array encode rᵢ values for each pairwise corresponding θᵢ.

13. The system according to claim 12, further comprising
assigning each resulting (rᵢ, θᵢ) pair a memristive device of the second crossbar array tile, and
analyzing the memristive device of the second crossbar array tile by
upon identifying combinations of (r, θ), applying constant width or constant amplitude programming pulses to the respective memristive devices.

14. The system according to claim 13, further comprising
selecting the memristive device of the second crossbar array tile having received a highest number of programming pulses, wherein the suitable combinations of (r, θ) relating to the selected memristive device correspond to the polar coordinates (rₛ, θₛ) of a line in the image before the vectorization.

15. The system according to claim 14, further comprising
determining a set of Cartesian coordinates (x_{L}, y_{L}) of the line by
(i) diagonally programming the memristive devices of the third crossbar array tile with conductance values G_{i,i} corresponding to determining conductance values GL=−cos θₛ/sin θₛ, and
(ii) applying amplitude signal value pulses of pixels of the vectorized image, the pixels having Cartesian coordinates xᵢ, i=1 . . . n, to e word lines of the third crossbar array tile, and
(iii) using resulting signals pulses yi, i=1 . . . n on bit lines of the third crossbar array tile such that value pair (xi, yi) represent an edge in the image.

16. The system according to claim 12, wherein the memristive devices comprise PCM devices, resistive memories, ferroelectric memories, magnetic tunnel junctions, electro-chemical memories, floating based memories, and charge based memories.

17. The system according to claim 11, wherein each of the crossbar arrays comprise at least one of an analog-to-digital converter for each bit line of the crossbar arrays, a combined digital processing unit for all bit lines of the crossbar array, I/O logic and command control circuitry, a data buffer, address-decoding circuitry, a read/write circuitry.

18. The system according to claim 11, wherein the transformation is a Hough transformation.

19. The system according to claim 11, wherein the at least three crossbar tiles of the memristive computing crossbar array are different sub-crossbar array of a larger memristive computing crossbar array using coming interfacing circuits.

20. A computer program product for implementing a shape detection transformation using an integrated memristive computing crossbar array having at least three crossbar tiles, said computer program product comprising a computer readable storage medium having program instructions embodied therewith, said program instructions being executable by one or more computing systems or controllers to cause said one or more computing systems to
use a first crossbar array tile of the at least three crossbar tiles for a parametric space transformation of the shape detection transformation, wherein data of an image in a vectorized form is used as input for the first crossbar array,
use an output of the first crossbar array tile as input for a second crossbar array tile of the at least three crossbar tiles for an accumulation operation of the shape detection transformation, and
use an output of the second crossbar array tile as input for a third crossbar array tile of the at least three crossbar tiles for a shape tracing operation of the transformation, such that an output of the third crossbar array determines parameter values of a detected shape.
